(19) United States
(12) Patent Application Publication
(10) Pub. No.: US 2015/0263303 A1
(43) Pub. Date: Sep. 17, 2015

(54) POLARIZATION SENSITIVE DEVICES UTILIZING STACKED ORGANIC AND INORGANIC PHOTOVOLTAICS AND RELATED METHODS

(71) Applicant: North Carolina State University, Raleigh, NC (US)

(72) Inventors: Michael Kudenov, Raleigh, NC (US); Brendan O'Connor, Raleigh, NC (US); Omar Awartani, Raleigh, NC (US)

(21) Appl. No.: 14/645,882

(22) Filed: Mar. 12, 2015

Related U.S. Application Data
(60) Provisional application No. 61/951,803, filed on Mar. 12, 2014.

(51) Int. Cl. H01L 51/44; H01L 51/00

(52) U.S. Cl. CPC H01L 51/447; H01L 51/442; H01L 51/0021; H01L 51/0002

(57) ABSTRACT

Polarization sensitive devices utilizing stacked organic and inorganic photovoltaics and related methods are disclosed. According to an aspect, a polarization sensitive photovoltaic (PV) cell may include an anode, a cathode, and a photoactive layer and a polarizing structure between the anode and the cathode. The photoactive layer may be formed from inorganic or organic materials. The polarizing structure may be integrated with the photoactive layer. Two or more PV cells may be stacked along an axis to form a polarization sensitive device such as, for example, a polarimeter.

### CROSS REFERENCE TO RELATED APPLICATION

This application claims priority to and the benefit of U.S. Provisional Patent Application No. 61/951,803, titled POLARIZATION SENSITIVE DEVICES UTILIZING STACKED ORGANIC AND INORGANIC PHOTOVOLTAICS, AND RELATED METHODS, and filed Mar. 12, 2014, the disclosure of which is incorporated herein by reference in its entirety.

### TECHNICAL FIELD

The present invention relates generally to polarization sensitive devices such as photovoltaic (PV) cells and polarimeters, including polarization sensitive detectors utilizing stacked organic and inorganic photovoltaic architectures.

### BACKGROUND

Optoelectronic devices include photovoltaic (PV) devices such as PV cells and photodetectors, and electroluminescent (EL) devices such as light-emitting diodes (LEDs) and laser diodes (LDs). A PV cell generates electrical power when light (electromagnetic radiation) is incident upon its active layer. The power may be utilized by a resistive load (e.g., battery, electrical power-consuming device, etc.) connected across the PV cell. For example, a solar cell is a type of PV cell that utilizes sunlight as the source of incident electromagnetic radiation. A photodetector operates similarly to a PV cell, but is configured to detect the occurrence of incident light and/or measure the intensity, attenuation or transmission of incident light and thus may be utilized in various optical sensing and imaging applications. The operation of a photodetector typically entails the application of an external bias voltage whereas the operation of a PV cell does not. Photodetectors are utilized in instruments that detect light or measure optical properties and in imaging devices (e.g., digital cameras) that produce still photographs and/or video streams from an observed scene. The design of such devices is typically based on a focal plane array (FPA) composed of several photodetectors and coupled to imaging electronics (e.g., read-out chips).

Conventionally, the fabrication of PV devices and other optoelectronic devices has entailed the use of bulk and thin-film inorganic semiconductor materials to provide p-n junctions for separating electrons and holes in response to absorption of photons. In particular, electronic junctions are typically formed by various combinations of intrinsic, p-type doped and n-type doped silicon. In addition, Group III-V materials such as indium-gallium-arsenide (InₓGa_{y}As, x+y=1, 0<x≦1, 0≦y≦1), germanium (Ge) and silicon-germanium (SiGe), and other inorganic materials have been utilized to modify or extend the wavelength range of sensitivity of such devices. In operation, when the energy of an incident photon is higher than the band gap value of the semiconductor, the photon can be absorbed in the semiconductor material. Absorption results in the photon's energy exciting a negative charge (electron) and a positive charge (hole), or electron-hole pair. The occurrence of photoconductive and photovoltaic effects requires charge separation. That is, the electron and the hole must first be separated before being collected at and extracted by the opposing electrodes (anode and cathode) of the device. If the charges do not separate they can recombine and thus not contribute to the electrical response generated by the device.

Currently, research is being directed toward PV devices based on organic materials (polymers and small molecules) as an alternative to inorganic based semiconductors. The active region in organic based devices includes a heterojunction formed by an organic electron donor layer and an organic electron acceptor layer. In operation, a photon absorbed in the active region excites an exciton, i.e., an electron-hole pair in a bound state that can be transported as a quasi-particle. The photogenerated exciton becomes separated (dissociated or “ionized”) when it diffuses to the heterojunction interface. Analogous to the case of inorganic PV devices, it is desirable to separate as many of the photogenerated excitons as possible and collect them at the opposing electrodes before they recombine. Organic semiconductor devices may offer a lower-cost alternative to inorganic semiconductor devices. Other advantages of organic materials include their ability to be deposited on flexible substrates, tunable properties through material synthesis, and their use of earth abundant materials. A unique characteristic of polymer semiconductors is that they commonly have an optical transition dipole moment (π−π*) that is aligned along the polymer backbone. Thus, aligning the polymer backbone uniaxially in the plane of the film results in anisotropic optoelectronic properties. Aligning polymer semiconductors has been exploited to study charge transport in organic field effect transistors (OFETs) and for polarized electroluminescence in organic light emitting diodes (OLEDs).

PV devices may be fabricated so as to be polarization sensitive. Polarization sensitive PV devices may be beneficial for a number of applications, including polarized light detectors (e.g. remote detection), power generation (e.g., polarized light harvesting in LCD displays), and imaging polarimetry.

Imaging polarimetry is utilized to measure the 2-dimensional (2D) Stokes parameter distribution of a scene. It is a valuable tool in many applications, such as the characterization of aerosol size distributions, distinguishing man-made targets from background clutter in target acquisition and change detection, quality control for evaluating the distribution of stress birefringence, resolving data channels in telecommunications, and for evaluating biological tissues in medical imaging. The Stokes vector is defined as:

$$S ( x , y ) = [ \begin{matrix}{S}_{0} ( x , y ) \\ {S}_{1} ( x , y ) \\ {S}_{2} ( x , y ) \\ {S}_{3} ( x , y )\end{matrix} ] = [ \begin{matrix}{I}_{0} ( x , y ) + {I}_{90} ( x , y ) \\ {I}_{0} ( x , y ) - {I}_{90} ( x , y ) \\ {I}_{45} ( x , y ) - {I}_{35} ( x , y ) \\ {I}_{R} ( x , y ) - {I}_{L} ( x , y )\end{matrix} ] , \qquad ( 1 )$$

where x, y are spatial coordinates in the scene, S₀ is the total power of the beam, S₁ denotes preference for linear 0° over 90°, S₂ for linear 45° over 135°, and 53 for right over left circular polarization states. By measuring all four elements of S (x,y), the complete spatial distribution of the polarization state can be determined. Typically, Stokes parameters are measured by recording four intensity measurements using different configurations of polarization analyzers. Instruments that can measure complete Stokes vectors within a camera's single integration time include division of focal plane (DoFP) polarimeters, division of amplitude (DoAM) polarimeters, division of aperture (DoA) polarimeters, and channeled imaging polarimeters (CIPs).

Current polarization sensitive focal plane array (FPA) technologies rely on super-pixel approaches in which the FPA's pixels are segregated into 2×2 pixel unit cells. However, since the Stokes parameters are calculated by subtracting adjacent pixels, this approach suffers from significant artifacts when measuring high spatial resolution polarization data. While post processing can resolve some of these deficiencies, it often comes at a further reduction to the data's spatial resolution.

FIG. 1A is a schematic view of a DoFP polarimeter of known design. Each 2×2 pixel unit cell contains four pixel-sized polarization analyzers, which typically consist of 0°, 45°, 90°, and 135° linear wire-grid polarizers. Wave plates may also be employed. FIG. 1B is a schematic view of a color CCD (charge coupled device) of known design, which shows that the approach illustrated in FIG. 1A is analogous to color filter patterns on consumer digital cameras. While this approach offers a compact and rugged polarimetric sensor, it reduces the spatial resolution of the focal plane array by a factor of four. Additionally, it is sensitive to spatial sampling error. This is because the Stokes parameters are calculated through arithmetic subtraction between orthogonal intensities. Therefore, any high contrast features with spatial frequencies that are greater than the sensor's Nyquist frequency experience error. While this error can be reduced, it reduces the spatial resolution even further to achieve this (i.e., a greater than four-fold reduction in the spatial resolution).

The CIP is an alternative technology that addresses some of spatial sampling limitations of the DoFP polarimeter. In the CIP's operation, spatial sampling of the Stokes parameters is achieved by amplitude modulating them onto spatial carrier frequencies. These carrier frequencies are usually generated by a prismatic or birefringent interferometer, such as a Savart plate, Wollaston prism, or a polarization grating. However, while CIP resolves some of the DoFP's Nyquist sampling limitations, it comes at a nine-fold reduction of the focal plane array's spatial resolution. While some solutions exist to resolve the DoFP's spatial resolution limit, they require temporal scanning. This removes the system's snapshot ability, which is often the desired characteristic for using a DoFP approach.

FIG. 2 is a schematic view of a coincident four-detector polarimeter of known design. The device is a single-ray device in which the four detectors are positioned at distances from each other and oriented at angles with respect to each other. By using a series of reflections off the four detectors, the system is able to analyze the complete polarization state of a single incident ray (i.e., a single “spatial location”). This can be achieved because each reflection is only partially analyzing the incident polarization state of the light. Therefore, the complete polarization state can be recovered using conventional data-reduction matrices. This is contrary to a wire-grid polarizer approach observed in DoFP, for instance, in which each pixel is fully analyzed. Therefore, the polarization state, after transmission through the wire-grid, cannot be resolved further by subsequent detection processes. However, the detectors of the device of FIG. 2 are not integrated together in a single-pixel architecture, and the resulting device is not compact. This lack of compactness, plus the limited field of view of the device, means that these devices cannot be arranged to sample a 2-dimensional image as can be created with the DoFP or CIP approaches.

In view of the foregoing, there is a continuing need for polarization sensitive devices exhibiting robust architecture. There is also a need for single-pixel polarization sensitive devices useful for optical detection or measurement and providing high spatial resolution. There is also a need for polarization sensitive devices that merge the advantages provided by different types of known devices without also suffering from the disadvantage of such known devices.

### SUMMARY

To address the foregoing problems, in whole or in part, and/or other problems that may have been observed by persons skilled in the art, the present disclosure provides methods, processes, systems, apparatus, instruments, and/or devices, as described by way of example in implementations set forth below.

According to one embodiment, a polarization sensitive photovoltaic (PV) cell includes: an anode; a cathode; a photoactive layer between the anode and the cathode; and a polarizing structure between the anode and the cathode, wherein at least one of the anode and the cathode is transparent.

According to another embodiment, a polarization sensitive photovoltaic (PV) device includes: a plurality of PV cells, including at least a first PV cell and a second PV cell. The first PV cell includes a first transparent or semi-transparent anode; a first transparent or semi-transparent cathode; a first photoactive layer between the first anode and the first cathode; and a polarizing structure between the first anode and the first cathode. The second PV cell includes a second transparent or semi-transparent anode; a second transparent or semi-transparent cathode; and a second photoactive layer between the second anode and the second cathode. The first PV cell and the second PV cell are stacked along a device axis such that the first cathode is in electrical communication with the second anode.

According to another embodiment, a method for fabricating a polarization sensitive photovoltaic (PV) cell includes: forming an anode, a cathode, and a photoactive layer such that the photoactive layer is between the anode and the cathode, wherein at least one of the anode and the cathode is transparent; and forming a polarizing structure between the anode and the cathode.

According to another embodiment, a method for fabricating a polarization sensitive photovoltaic (PV) device includes: fabricating a first PV cell; fabricating one or more additional PV cells, with or without respective polarizing structures; and stacking the first PV cell and the one or more additional PV cells along an axis.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIG. 1A is a schematic view of a DoFP polarimeter of known design.

FIG. 1B is a schematic view of a color CCD (charge coupled device) of known design.

FIG. 2 is a schematic view of a single spatial location four-detector polarimeter of known design.

FIG. 3A is a schematic view of an example of a polarization sensitive photovoltaic (PV) device or cell according to some embodiments.

FIG. 3B is a schematic view of an example of a polarization sensitive PV device according to some embodiments.

FIG. 4A is a schematic perspective view of an example of a single-cell PV device according to some embodiments.

FIG. 4B is a view similar to FIG. 4A, but highlighting a polarizing structure of the PV device.

FIG. 5A is a schematic perspective view of an example of a PV cell that includes a polarizing structure oriented at 0°.

FIG. 5B is a schematic perspective view of an example of a PV cell that includes a polarizing structure oriented at 45°.

FIG. 5C is a schematic perspective view of an example of a PV cell that includes a polarizing structure oriented at 90°.

FIG. 5D is a schematic perspective view of an example of a PV cell that has no polarizing structure.

FIG. 6 is a schematic perspective view of a polarimetric single-pixel detector formed by stacking together the PV cells illustrated in FIGS. 5A to 5D along a device axis.

FIG. 7 is a schematic perspective view of an example of an organic solar cell with a known architecture.

FIG. 8 is a set of plots of absorbance (arbitrary units) as a function of wavelength (nm) measured in a P3HT:PCBM bulk heterojunction film with isotropic in-plane orientation of the P3HT (0% strain) and uniaxial in-plane alignment of P3HT (100% strain applied to the film) with incident light polarized parallel and perpendicular of the strain direction, in which straining is followed by thermal annealing at 120° C. for ten minutes.

FIG. 9 is a schematic view of an example of an organic PV device according to some embodiments.

FIG. 10A is a set of absorbance spectra for strain-aligned P3HT:PCBM blend films with incident light polarized parallel (para) and perpendicular (perp) to the strain direction; the absorbance was measured for P3HT:PCBM films cast on glass coated with PEDOT:PSS and ITO, and corrected by subtracting the absorbance of a PEDOT:PSS and ITO coated glass substrate reference.

FIG. 10B is a set of plots for dichroic ratio and short circuit current (J_{SC}) anisotropy as a function of applied strain for the samples evaluated in FIG. 10A, with line fits to the data.

FIG. 11 is a set of plots of current density—voltage for strain-aligned OPV cells under polarized light parallel (para) and perpendicular (perp) to the strain direction with an intensity of 41 mW cm⁻²; the data is presented for 0%, 50% and 100% strained P3HT:PCBM films.

FIG. 12 is a set of plots for short circuit current (J_{SC}), open circuit voltage (V_{OC}), fill factor (FF), and power conversion efficiency (η) measured from the current—voltage curves given as a function of strain; the data is provided for performance under polarized light parallel (para) and perpendicular (perp) to the strain direction under 41 mW cm⁻² intensity.

FIG. 13 is a set of plots of External Quantum Efficiency (EQE) for the strain-aligned OPV cells under polarized light shown for three strains (0%, 50% and 100%); the legend provides the level of strain applied to the P3HT:PCBM layer with light polarized parallel (para) and perpendicular (perp) to the strain direction.

FIG. 14 is a set of plots of normalized absorbance (arbitrary units) as a function of wavelength (nm) for strain aligned P3HT:PCBM films with light polarized (para) and perpendicular (perp) to the strain direction.

FIG. 15 is a set of current-voltage characteristics for the polarization sensitive photovoltaic cells for various levels of strain applied to the P3HT:PCBM layer, with current density given in mA cm⁻²; the measurements are given for linear polarized light parallel (para) and perpendicular (perp) to the strain direction at an intensity of 41 mW cm⁻².

FIG. 16 is a set of plots of External Quantum Efficiency (EQE) as a function of wavelength (nm) for the strain-aligned OPV cells under polarized light shown for several strain conditions; the legend provides the level of strain applied to the P3HT:PCBM layer with light polarized parallel (para) and perpendicular (perp) to the strain direction.

FIG. 17 is a plot of FPA data with corresponding fitted lines for microbolometers; the temperature T_{bb} of the black body was varied from 15° C. (288K) to 55° C. (328K) in 5° C. increments.

FIG. 18A is a diagram depicting an example experimental setup for calibrating polarimeter in accordance with embodiments of the present disclosure.

FIG. 18B is a circuit diagram of an example reverse biased OPV circuit in accordance with embodiments of the present disclosure.

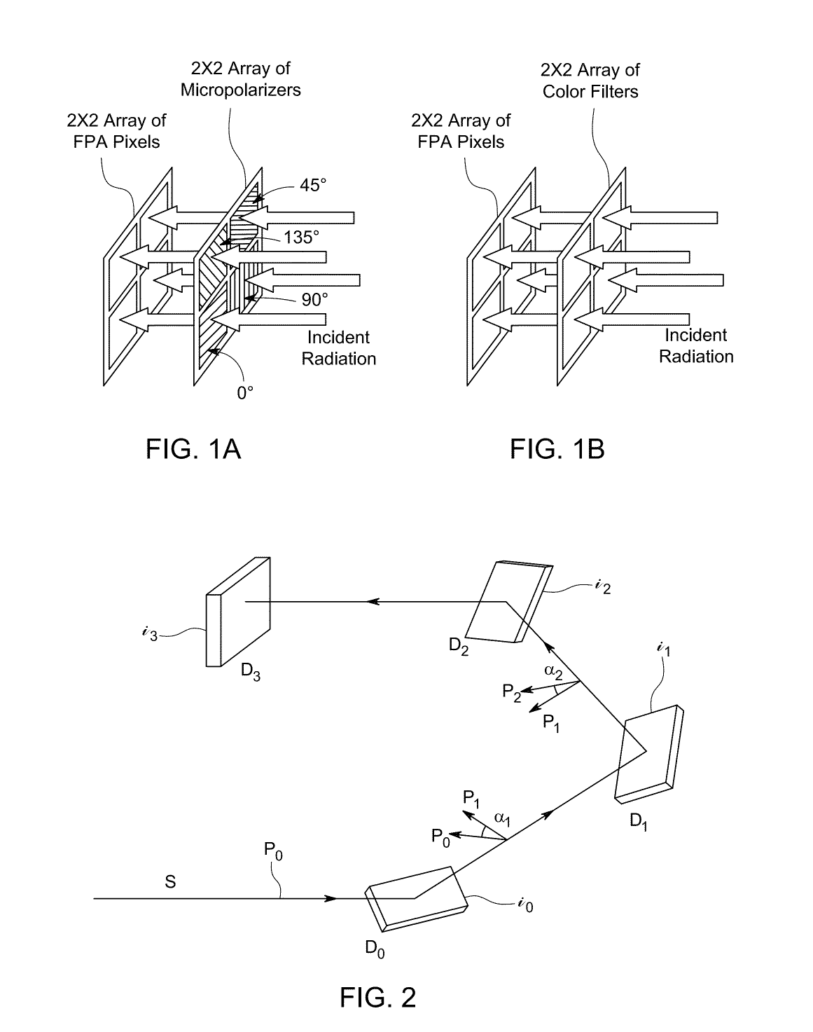

### DETAILED DESCRIPTION

The present disclosure describes embodiments of a new type of polarization sensitive photovoltaic-based device. The device absorbs light preferentially based on polarization state. Electrical current photogenerated by the device may be utilized for energy storage, power supply, or various detection/measurement functions. In one or more embodiments, the device may be considered as having an optimized architecture that merges desirable features from conventional devices such as those described in the Background section of the present disclosure. In one or more embodiments, the device generates current useful for imaging and with substantially improved spatial resolution. The device includes a photovoltaically active semiconductor region that may be inorganic or organic based. In some embodiments, the device includes a periodic structure embedded directly into the p-n junction of an inorganic photoactive region of the device. In other embodiments, the device includes a periodic arrangement of aligned conjugated polymers that are part of an organic photoactive region of the device. In some embodiments, the device includes a three-dimensional (vertical) stack of photovoltaic cells. Varying the dimensions and orientation of the periodic structure, or the alignment of the conjugated polymer, in the cells, enables the device to preferentially absorb certain polarization states directly within the active regions. This attribute is opposite to that of the conventional wire-grid polarizer, which preferentially reflects certain polarization states. The stacked architecture of the device disclosed herein enables it to operate as a single-pixel device and allows it to be extremely compact and rugged, as well as to provide substantially increased spatial resolution as compared with conventional polarimeter-type devices (for example, spatial resolution is quadrupled in comparison to certain known devices). The multi-cell device as a single, integrated unit may be configured to measure all four Stokes parameters coincidently while nearly eliminating spatial registration errors.

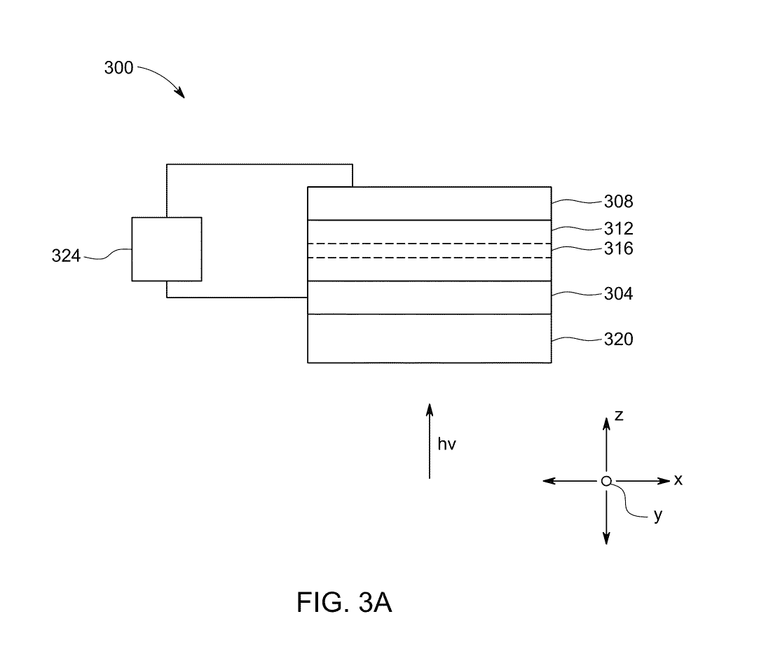

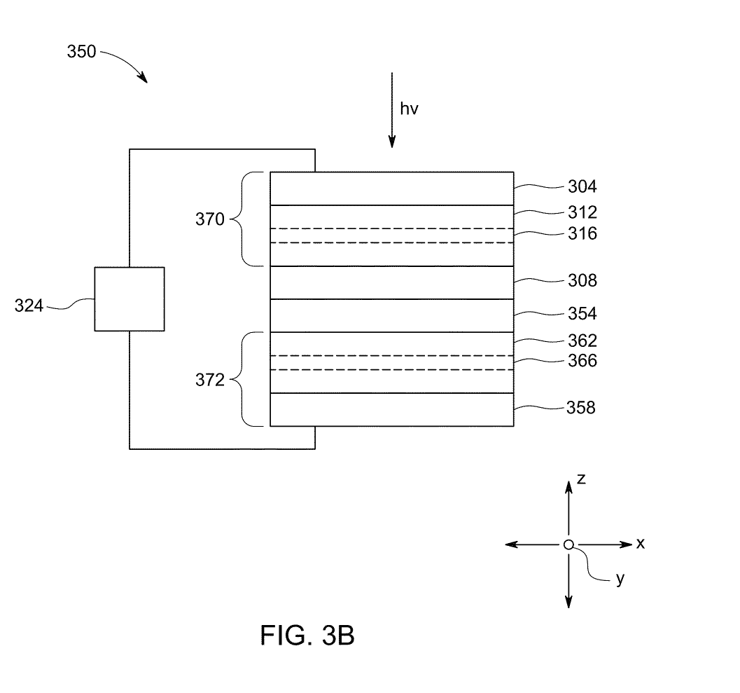

FIG. 3A is a schematic view of an example of a polarization sensitive photovoltaic (PV) device or cell 300 according to some embodiments. The PV cell 300 generally includes a three-dimensional (or vertical) arrangement of layers (or films) of material. For reference purposes, FIG. 3A shows a three-dimensional coordinate system with x-, y- and z-axes. The layers are stacked along the z-axis, which may be referred to as the device axis. The layers may be generally planar structures having thicknesses along the device axis and transverse (x and y) dimensions in the x-y plane (i.e., into the drawing sheet). The x-y plane may be referred to as the transverse plane orthogonal to the device axis. In typical embodiments, the transverse dimensions of each layer are large in comparison to its thickness, as appreciated by persons skilled in the art of fabrication of optoelectronics devices. In typical embodiments, the layers are polygonal, although in other embodiments may be disk-shaped or irregularly shaped. In typical embodiments, the layers are generally flat (i.e., not angled or bent relative to the transverse plane, although in other embodiments may be curved.

In the illustrated embodiment, the PV cell 300 includes a transparent anode 304 (or first electrode, or first electrically conductive layer), a cathode 308 (or second electrode, or second electrically conductive layer), a photoactive layer or region 312 between the anode 304 and the cathode 308, and a polarizing structure 316 between the anode 304 and the cathode 308. In the present context, “transparent” means optically transparent and unless otherwise specified encompasses relative terms such as partially transparent, semitransparent and translucent. A transparent layer is one which transmits light (photons) through its thickness. The light, which is able to be transmitted through a given layer, falls within some range of wavelengths of interest to the design and function of the PV cell 300, such as visible light and/or wavelengths shorter and/or longer than visible wavelengths. The photoactive layer 312 is sensitive to at least some sub-range of the range of wavelengths to which the anode 304 is transparent.

The anode 304 may generally be composed of any electrically conductive material, such as various metals (e.g., platinum, gold, silver, aluminum, copper, etc.), ceramics, or conductive polymers. In a typical embodiment in which the anode 304 is to receive and transmit incident light, the anode 304 is composed of a suitable optically transparent, electrically conductive material. In one non-limiting example, the anode 304 is composed of indium tin oxide (ITO) or other transparent conductive oxide (TCO). Depending on its composition, the transparency of the anode 304 may further depend on its thickness. The cathode 308 may generally be composed of any electrically conductive material. In some embodiments, the cathode 308 may be optically reflective (or semi-reflective) such that light unabsorbed by the photoactive layer 312 is directed back into the photoactive layer 312. In other embodiments, the cathode 308 may be opaque (i.e., primarily absorbs photons). In other embodiments, the cathode 308 may be transparent. In some embodiments, the anode 304 is composed of a high work function material (e.g., ITO) and the cathode 308 is composed of a low work function material (e.g., aluminum). While the anode 304 and cathode 308 are schematically depicted in FIG. 3A as single layers, it will be understood that the anode 304 and/or cathode 308 may include two or more layers of different materials or may include an alloy or blend of different materials.

The photoactive layer 312 may generally be one or more layers of material suitable for photovoltaic activity, i.e., generating electrical current in response to absorption of light incident on the PV cell 300 (e.g., as transmitted by the anode 304). Typically, and as appreciated by persons skilled in the art, the photoactive layer 312 includes a junction of two different (or differently doped) materials. In some embodiments, the junction is a p-n junction of inorganic semiconductors, i.e., the interface of a p-type material and an n-type material. The inorganic semiconductors utilized may be intrinsically or extrinsically p-type or n-type. Examples include, but are not limited to, single-crystal, polycrystalline, and amorphous silicon. In other embodiments, the junction is a heterojunction of an electron donor material and an electron acceptor material. The electron donor material and electron acceptor material may be organic compounds, in particular conjugated polymers. The photoactive layer 312 may also have a hybrid composition that includes both inorganic and organic materials.

In some embodiments, the polarizing structure 316 is embedded in or integral with the photoactive layer 312, as schematically depicted in FIG. 3A. The polarizing structure 316 may be a modification or processed feature of a p-n junction or organic semiconductor material that is part of the photoactive layer 312. Generally, the polarizing structure 316 is or includes multiple structures or features aligned in parallel with each other. As one example, the polarizing structure 316 may be or include a grating-like periodic structure formed at or into a p-n junction by any suitable microfabrication technique known to persons skilled in the art (e.g., lithography, wet etching, dry etching, microdrilling, laser ablation, etc.). As another example, the polarizing structure 316 may be or include aligned molecules (e.g., parallel polymer backbones), as described further below. In either case, the polarizing structure 316 is configured to render the photoactive layer 312 preferentially sensitive to incident light having a particular polarization state. As a result, the photoactive layer 312 behaves as a “weak” diattenuator with the potential of also inducing some amount (or no amount) of polarization retardance. That is, light incident on the polarizing structure 316 is preferentially absorbed and/or retarded by the aligned structures parallel to the incident polarizations, while other light is transmitted through the polarizing structure 316. Non-limiting examples of photoactive layers 312 and associated polarizing structures 316 are described below.

The PV cell 300 and its various layers may be fabricated by a variety of techniques known in fields relating to microfabrication (e.g., microelectronics, microfluidics, micro-electro-mechanical systems (MEMS), etc.). The process steps taken for forming the various layers depend in part on their compositions and the compatibility of the process with the underlying surface on which a particular layer is formed. As appreciated by persons skilled in the art, fabrication techniques include, but are not limited to, electroplating, vacuum deposition, solution processing, spin-coating, spray coating, dip coating, doctor blading, printing, lamination, adhesion, etc., and related techniques. By way of example, FIG. 3A illustrates a substrate 320 on which the anode 304 is formed. Hence, one example of a method for fabricating the PV cell includes forming the anode 304 on the substrate 320, forming the photoactive layer 312 on the anode 304, forming the polarizing structure 316 (examples of which are described below), and forming the cathode 308 on the photoactive layer 312. The substrate 320 may be a transparent material such as, for example, glass. Depending on the embodiment, the substrate 320 may remain as part of the final device or may be removed at some stage of the fabrication process. In some embodiments, one or more of the layers may be formed or fabricating separately and then added to the composite structure being fabricated. In some embodiments, the polarizing structure 316 may be added to the photoactive layer 312, or the photoactive layer 312 may be processed or engineered to create the polarizing structure 316, and then the photoactive layer 312 is added to the composite structure being fabricated.

It will be understood that depending on the embodiment, other layers not specifically shown in FIG. 3A may be provided between the anode 304 and cathode 308 for various purposes. Examples include, but are not limited to, electron transport layers, electron blocking layers, hole transport layers, hole blocking layers, exciton blocking layers, birefringent layers such as half-wave plates and quarter-wave plates, optical spacers, spectral filters, etc.

As further illustrated in FIG. 3A, the PV cell 300 (i.e., the anode 304 and cathode 308) may be placed in electrical communication with an electrical circuit 324. The type of electrical circuit depends on the configuration (or operation, or function) of the PV cell 300. For example, the PV cell 300 may be configured as a polarization sensitive PV cell for storing energy (e.g., a solar cell), in which case the circuit 324 may be a battery or other type of energy-storing external load, or a power-consuming load. As another example, the PV cell 300 may be configured as a polarization sensitive photodetector (or measurement device) for performing a variety of polarization-related detection/measurement functions. In this case, the circuit 324 may be or include a bias voltage source, a read-out integrated circuit (ROIC), etc.

FIG. 3B is a schematic view of an example of a polarization sensitive PV device 350 according to some embodiments. The PV device 350 generally includes a plurality of individual PV cells (or detector elements, or detection stages) stacked along the device axis. For simplicity, only a first PV cell 370 and a second PV cell 372 are illustrated, with the understanding that other embodiments may include more than two PV cells. Each PV cell may be configured as generally described above in conjunction with FIG. 3A. All PV cells of the PV device 350 may include a polarizing structure, or one or more of the PV cells may omit a polarizing structure. In the illustrated embodiment, the first PV cell 370 includes a first transparent anode 304, a first transparent cathode 308, a first photoactive layer 312 between the first anode 304 and the first cathode 308, and a (first) polarizing structure 316 between the first anode 304 and the first cathode 308. The second PV cell 372 includes a second transparent anode 354, a second cathode 358, a second photoactive layer 362 between the second anode 354 and the second cathode 358, and optionally a second polarizing structure 366 between the second anode 354 and the second cathode 358. The PV device 350 may be utilized as a polarization sensitive optical detector or measurement instrument, such as a partial or complete Stokes polarimeter, which may communicate with an external circuit 324 such as, for example, a bias voltage source or an ROIC. The first PV cell 370 and the second PV cell 372 are stacked along the device axis such that the first cathode 308 is in electrical communication with the second anode 354. Intermediate or internal electrodes such as the first cathode 308 and the second anode 354 are transparent to enable components of the incident light to reach each photoactive layer of the PV device 350. The PV device 350 thus may be characterized as a single-ray, single-pixel device, which is enabled by the stacked architecture and the weak diattenuation provided by the photoactive layers that include polarizing structures.

It will be noted that in a conventional PV cell, the back electrode thickness typically is on the order of 100 nm. However, to realize a transparent metallic cathode, the thickness may be decreased significantly, for example on the order of 10 nm. This can allow most of the light that is not absorbed by the photoactive layer to be transmitted into the subsequent PV cell. In addition to thin metal films, other electrode material options suitable for efficient charge collection and transparency include, but are not limited to, graphene and metallic nanowire meshes.

In some embodiments, the PV device 350 is configured as a complete Stokes polarimeter. In this case, the PV device 350 includes four PV cells, i.e., a third PV cell (not shown in FIG. 3B) below the second PV cell 372 and a fourth PV cell (not shown in FIG. 3B) below the third PV cell. In one embodiment, the third PV cell includes a third polarizing structure and the fourth PV cell includes a photoactive layer but not a polarizing structure (although in other embodiments the fourth PV cell may include a polarizing structure). The respective polarizing structures (i.e., the set of parallel, aligned structures of each polarizing structure) are oriented at different angles to each other. That is, the first polarizing structure 316 is oriented at a first angle, the second polarizing structure 366 is oriented at a second angle different from the first angle, and the third polarizing structure is oriented at a third angle different from the first angle and from the second angle. Any reference datum may be utilized to define these relative angles or orientations. For example, the angle may be relative to the x-axis in the transverse plane. Thus, for example, taking the first angle of the first polarizing structure 316 as being 0°, the second angle of the second polarizing structure 366 may be 90° and the third angle of the third polarizing structure may be 45°. By this configuration, the respective PV cells generate four currents, allowing the complete polarization state of incident light to be calculated.

In some embodiments, the polarizing structure associated with a given photoactive layer between a given anode/cathode pair of one or more of the PV cells may include a plurality of portions or sections that have different polarization sensitivities. For example, the portions of such a polarizing structure may include respective arrays of parallel structures (e.g., bars or molecular backbones) oriented in different directions relative to each other.

It will be understood that, depending on the embodiment, other layers or components not specifically shown in FIG. 3B, such as for example wave plates, may be provided between the PV cells.

In other embodiments, a partial Stokes polarimeter may be realized by changing the number of PV cells provided in the PV device 350. For instance, two PV cells may be utilized to detect a single Stokes parameter, in conjunction with the S₀ component. Specifically, S₁/S₀, S₂/S₀, or S₃/S₀ ratios may be measured with two PV cells. Additionally, a complete Stokes polarimeter may be created using a two-PV cell structure in conjunction with a rotating or scanning element. For instance, a two-PV cell structure may be joined with a plurality of rotating linear polarizers, partial diattenuators, and/or general wave plates (including quarter and half-wave) to create a complete Stokes polarimeter. Such a polarimeter may benefit from a reduced number of measurements when compared to complete scanning systems.

In other embodiments, three PV cells may be provided in the PV device 350. This may enable, for instance, a complete linear polarization measurement such that S₁/S₀ and S₂/S₀ may be quantified. Generally, linear polarization dominates in remote sensing scenes, which is why this particular polarimeter would be of great interest. Additionally, orthogonally linearly polarized states are also employed in telecommunications, as opposed to circularly polarized states.

In other embodiments, the multi-cell PV device 350 may be configured for spectrally-resolved Stokes polarimeter measurements, which may enable the detection of the four Stokes parameters as a function of wavelength. Such an embodiment may be implemented by combining a spectrally-resolving element, such as a diffraction grating, prism, hologram, or interferometer, with one of the detector embodiments disclosed herein. Arranging PV cells in a linear array enables a full Stokes spectro-polarimeter that is capable of a continuous spectral measurement. In other embodiments, a multispectral Stokes polarimeter may be enabled using one of the detector embodiments disclosed herein in conjunction with a series of spectral filters. These filters may be variable (e.g., based on Lyot interference filters, liquid crystal tunable filters, acousto-optical tunable filters, or tunable Fabry Perot cavities), or they may be fixed thin-film dichroic or dye (absorption) filters. Furthermore, spectral selectivity for a multispectral approach may be achieved directly within the organic semiconductor material. This material may be synthesized with tunable spectral sensitivity and the spectral response may be tunable across the visible spectrum through design of the cell optical microcavity. This approach exploits the thin-film nature of the PV cell by creating an interference filter out of the cell such that placement of the PV cell within the cavity can enable spectral sensitivity tunability. Additionally, placing a different filter with unique spectral cutoff wavelengths (e.g., long pass or short pass) over each PV cell layer or group of layers would enable a similar capability of spectrally resolving the Stokes polarization parameters.

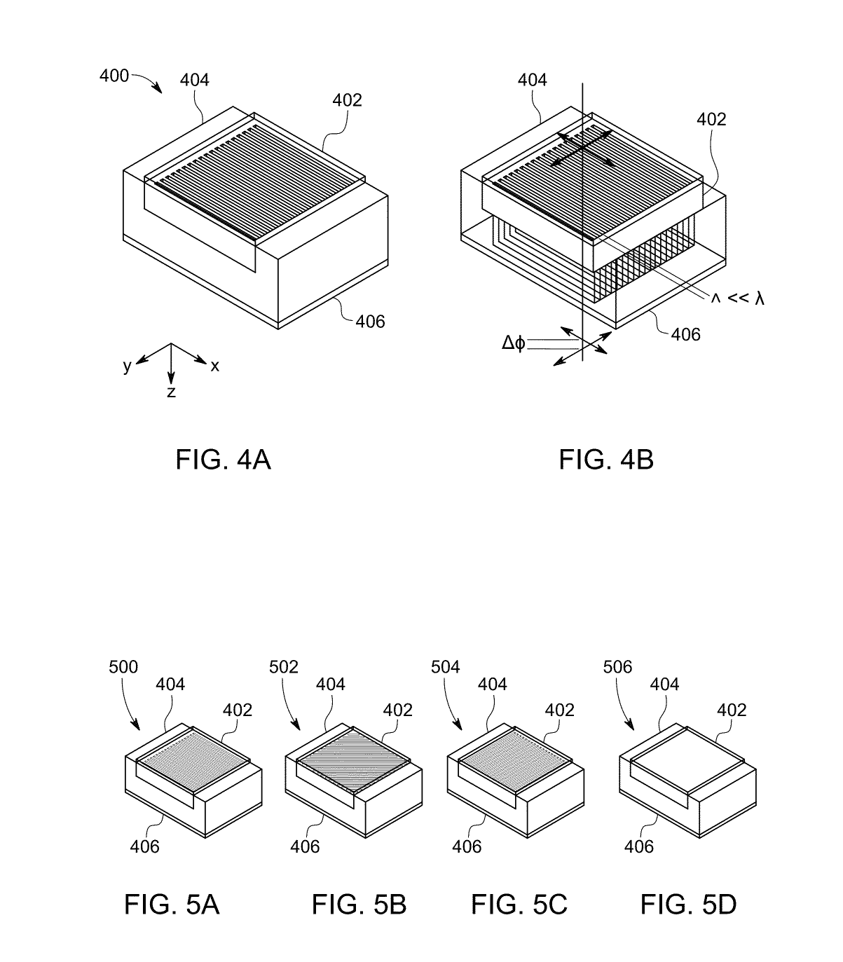

An example of an inorganic based PV device according to some embodiments will now be described with reference to FIGS. 4A to 6. FIG. 4A is a schematic perspective view of an example of a single-cell PV device (or PV cell) 400. FIG. 4B is a view similar to FIG. 4A, but highlighting a polarizing structure 402 of the PV device. The PV device 400 includes a photoactive layer between an anode 404 and a cathode 406. The photoactive layer includes a p-n junction. The polarizing structure 402 is formed (e.g., by etching) directly at the p-n junction. The polarizing structure 402 is formed as a grating-like spatially periodic structure. The periodic structure includes an alternating set of aligned (parallel) bars (or lines) and grooves. The period or pitch, Λ, of the periodic structure is sub-wavelength, i.e., Λ<<λ. The periodic structure may be considered as resembling or analogous to the wire grid of a wire-grid polarizer. However, unlike a wire-grid polarizer, the bars are not be composed of a preferentially reflective material but instead a preferentially absorptive material. The periodic structure enables the PV device 400 to preferentially absorb certain polarization states, and exactly which states are absorbed depends upon the geometry of the periodic structure (e.g., period, depth, duty cycle, and orientation). The propagation of orthogonally polarized light through the periodic structure is depicted in FIG. 4B. Using form birefringent structures as an operational analog, the periodic structure creates both polarized diattenuation (D) and retardance (Δφ). Optimizing the PV device's diattenuation and retardance may be accomplished by manipulating the structure's period (Λ), depth, and duty cycle. An example of this detection process is provided in FIG. 4B. A ray with orthogonal x and y polarization components is incident on the PV device. Upon transmission through the periodic p-n junction, some light is absorbed along x, thus creating charge within the depletion region. Conversely, light polarized in y transmits relatively unimpeded through the structure and is not absorbed. Therefore, this transmitted light can be further analyzed by an underlying PV device. Unlike the system described above in conjunction with FIG. 2, such a process is implemented in a monolithic, integrated device, i.e., at a single spatial location.

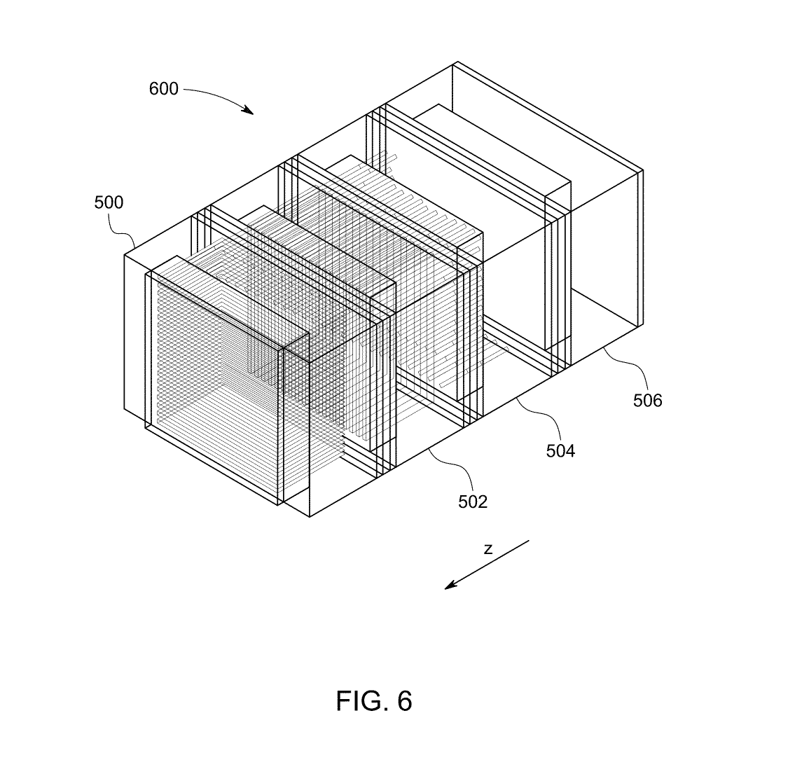

Because light transmits through the PV device 400 with only a partial change in polarization, several PV devices (or cells) may be stacked within the same spatial location to form a multi-cell PV device. Modification of the orientation of the bars of the periodic structure from cell to cell within the pixel can then produce a full Stokes parameter measurement. FIGS. 5A to 5D are schematic perspective views of four PV devices 500, 502, 504, and 506 similar to that illustrated in FIGS. 4A and 4B, but each configured differently as regards their respective polarizing structures 402. In FIG. 5A, the polarizing structure 402 has an orientation of 0°. In FIG. 5B, the polarizing structure 402 has an orientation of 45°. In FIG. 5C, the polarizing structure 402 has an orientation of 90°. In FIG. 5D, the PV cell 506 has no polarizing structure at its p-n junction. FIG. 6 is a schematic perspective view of a polarimetric single-pixel detector 600 formed by stacking together the PV cells 500, 502, 504, and 506 illustrated in FIGS. 5A to 5D along the device axis (z axis). In the illustrated example, the stacking order is such that the first, second, and third polarizing structures are oriented at 0°, 90° 45°, and 45°, respectively. The axially stacked arrangement enables four measurements containing the four Stokes parameters. Extracting the Stokes parameters can be achieved by establishing the data reduction matrix for each PV cell. An example of an instrument calibration process that may be implemented is discussed further below.

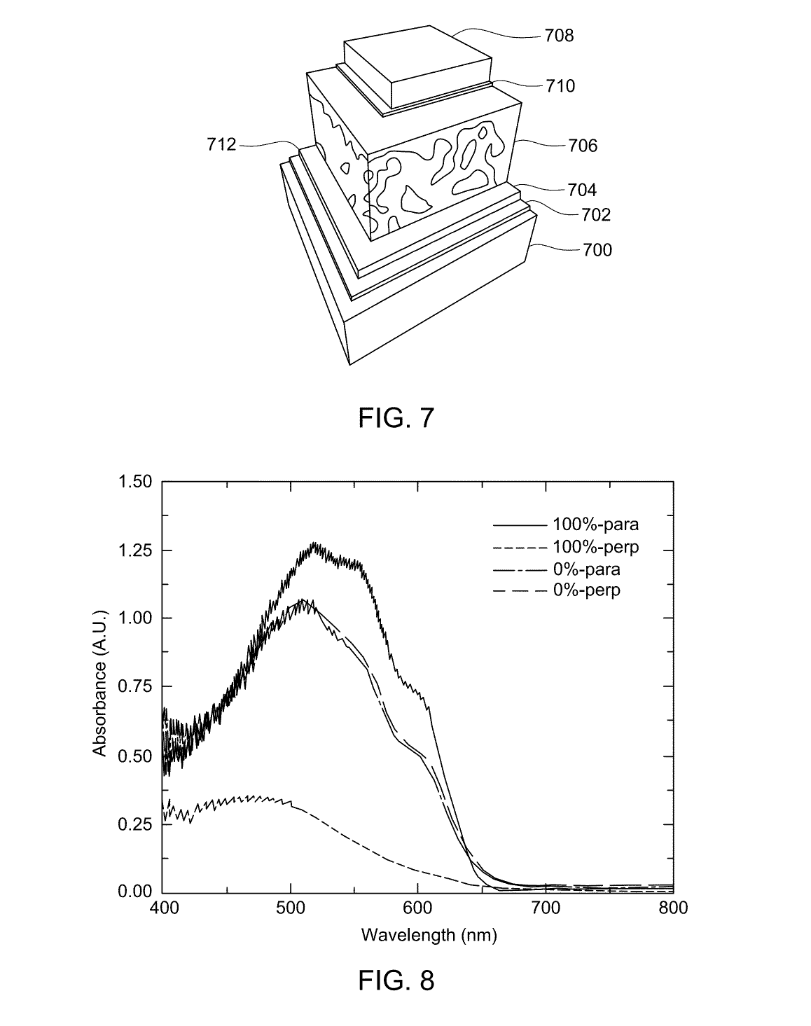

An example of an organic based PV device, or organic photovoltaic (OPV) device, according to some embodiments will now be described with reference to FIGS. 7 to 9. In this embodiment, the photoactive layer includes an organic heterojunction structure in the place of the p-n junction of the inorganic counterparts described above. The organic heterojunction includes an organic (electron) donor and an organic (electron) acceptor. As noted above, an OPV device can be used as a solar cell where the cell is connected to an external load, and the load is driven by photogenerated electrons (forward bias). An OPV device can also be operated in reverse bias and function as an efficient photodetector. In some cases, high quantum efficiency exceeding 75% may be achieved.

An example architecture for an organic solar cell is depicted in FIG. 7. The organic solar cell includes a glass substrate (2 mm) 700 with an indium tin oxide (ITO) anode (20-50 nm) 702 followed by photoactive organic semiconductor layers (100-300 nm), and finally a back cathode. In the illustrated example, the organic semiconductor layers are poly(3-hexylthiophene) (or P3HT, which functions as the primary light absorber) 704 and [6,6]-phenyl-C61-butyric acid methyl ester (or P3HT:PCBM, a fullerene derivative that functions as the electron acceptor) 706, which may be provided as a blend. Also in this example, the back cathode is aluminum (100 nm) 708 deposited on the transparent material lithium fluoride (1-2 nm) 710. As also illustrated, the organic solar cell may include a layer (20-40 nm) of the transparent conductive polymer poly(3,4-ethylenedioxythiophene):poly(styrenesulfonate) (or PEDOT:PSS) 712 between the ITO anode and the bulk heterojunction. The active organic layers may be small molecules or polymers. A significant advantage of the polymer semiconductors is the ability to solution process them in common solvents, thereby allowing for simple fabrication methods compatible with large area roll-to-roll manufacturing. Other advantages of OPVs include low production cost, flexibility and weight.

Significantly, the conjugated polymers employed in OPV devices may have an optical transition dipole moment nearly parallel to the polymer backbone. Using processing conditions to align the backbone along a single axis in the plane of the film leads to diattenuation. In a fashion similar to the inorganic based embodiments described above, an OPV device with an aligned conjugated polymer film results in preferential current generation that depends on the incident polarization state of the light.

In an organic PV device, the cathode is usually reflective and optically thick to maximize incident light absorption. However, both electrodes can be made semitransparent thereby allowing for a semitransparent detector. Additionally, diattenuation in a molecularly aligned photodetector is tunable and generally low (D˜0 to 6), which is ideal for the present embodiment. Similar to the inorganic based embodiments described above, semitransparent organic photodetectors may be fabricated where the transmitted polarization state is not fully analyzed such that subsequent detector cells may be utilized to measure the light's polarization state. The organic materials also have a strong optical absorption coefficient, making the OPV cell very thin (<500 nm), which may be stacked without adding significant width to the final product. The organic semiconductors may be bonded by Van der Waals forces, and thus do not have the lattice-matching requirements commonly required in covalent inorganic structures. Thus, this may enable the fabrication of a simpler monolithic and tandem single pixel detector.

To obtain aligned conjugated polymer films, there has been a range of demonstrated methods that include solution processing, nanostructured confinement, embossing, templated substrates, direct rubbing of the active film, directional solidification from a solution or within a magnetic field, and physical deformation methods. Physical deformation through large uniaxial strain is a particularly valuable method that is able to be applied to a common bulk heterojunction polymer-fullerene morphology utilized in OPV devices. The strain alignment approach also allows control over the level of polymer chain alignment resulting in a tunable diattenuation, making it a strong candidate for a single pixel polarimeter. The anisotropic absorbance of a strain aligned P3HT:PCBM bulk heterojunction film is given in FIG. 8, and is further described in the Example below. Specifically, FIG. 8 is a plot of absorbance (arbitrary units) as a function of wavelength (nm) measured in a P3HT:PCBM bulk heterojunction film strained by 100% (parallel), 100% (perpendicular), 0% (parallel), and 0% (perpendicular), in which straining is followed by thermal annealing at 120° C. for ten minutes. Diattenuation is observed in the preferential absorption of parallel light versus perpendicular light in the strained case.

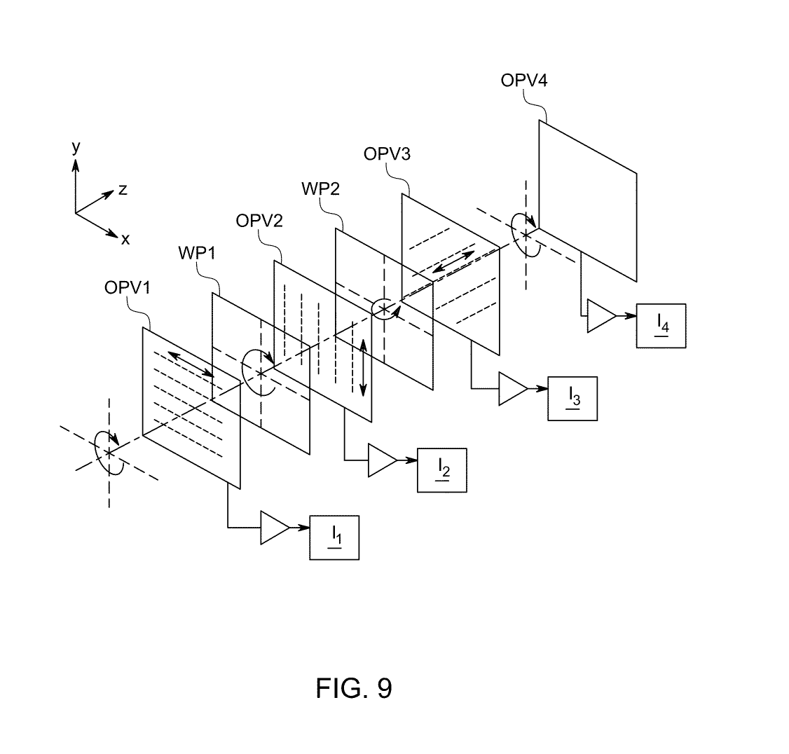

In a fashion similar to the inorganic PV devices described above, an OPV device may be fabricated as a layered structure in which multiple reverse-biased or unbiased OPV junctions cooperatively form a stacked polarimetric detector. FIG. 9 is a schematic view of an example of such a device according to embodiments of the present disclosure. This embodiment includes four reverse-biased or unbiased OPV cells OPV1-OPV4 in the xy plane, each of which contains a different amount of alignment at a unique orientation with respect to the x axis. In addition, waveplates WP1 and WP2 are positioned as shown. In FIG. 9, the parallel lines represent the aligned polymer backbones that serve as the polarizing structure in the first three OPV cells OPV1-OPV3, which are strain aligned. The alignment direction is indicated by arrows, and is effectively parallel to the direction of an incident linear polarization state's minimum transmission (i.e., maximum absorption is obtained for polarizations parallel to the stress) with the exception of OPV4. Because OPV4 is the last detector element, it can remain unstressed. However, stressing this element can be done to obtain a different variation of this embodiment. In the illustrated embodiment, OPV1, OPV2, and OPV3, are oriented at 0°, 90°, and 45°, respectively. Wave plates WP1 and WP2 have an optimal fast axis orientation and optimal retardance. Wave plates in these positions may enhance signal-to-noise ratio for measurements of circular polarization.

Another variation of this embodiment may include a plurality of wave plates, at arbitrary fast axis orientations, in between the detector elements. This may increase (or decrease) the sensitivity of the polarimeter to the detection of desired (or undesired) Stokes parameters. Such variation may also influence the condition number of the polarimeter's measurement matrix (see Eq. 12 below), which may directly influence the quality of the measured Stokes parameters. Ultimately, while it is known that each layer contains a certain amount of alignment-dependent diattenuation, it is envisioned that each layer can also contain a certain amount of retardance that can enable measurements of circular or elliptical polarization states (i.e., may increase sensitivity of the measurement to the S₃ Stokes parameter).

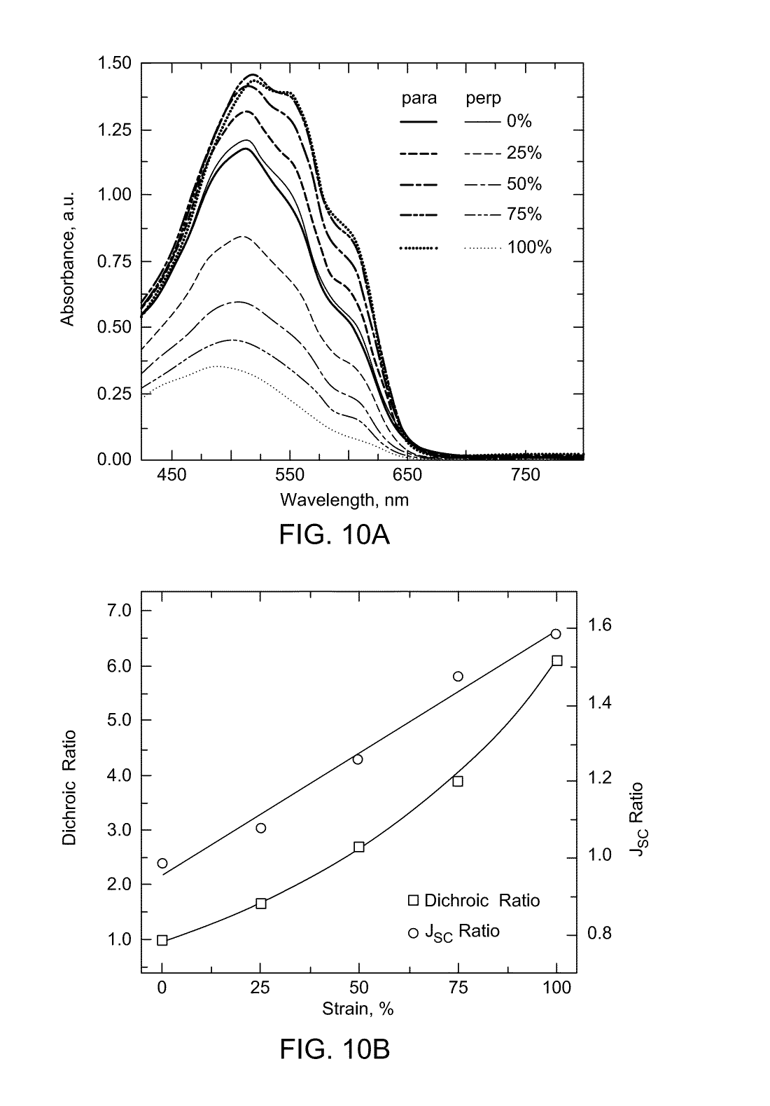

An example of fabricating organic PV cells with controlled polarization sensitivity will now be described with reference to FIGS. 10A to 16. Processing the polarized OPV cells began with spin casting poly(3,4-ethylenedioxythiophene):poly(styrenesulfonate) (PEDOT:PSS) films at 5,000 rpm onto a donor glass substrate followed by thermal annealing at 120° C. for 20 min. A P3HT:PCBM solution, with a 60:40 mass ratio in 1,2-dichlorobenzene at a concentration of 36 mg/ml, was then spun cast at 1,000 rpm for 60 s, resulting in a ≈220 nm thick film as determined by variable angle spectroscopic ellipsometry. The P3HT was obtained from Plextronics Inc. (Mn=50 kD) and the PCBM was obtained from Nano-C. The P3HT:PCBM film on the PEDOT:PSS coated glass substrate was then laminated onto a polydimethylsiloxane (PDMS) elastomer slab that was attached to a custom built strain stage. The composite stack was immersed in a deionized (DI) water bath where the PEDOT:PSS layer dissolves and the donor substrate detaches from the film. The P3HT:PCBM film, which was now adhered to the PDMS slab, was removed from the DI water and dried with N₂ gas. The composite was then strained and printed onto a receiving substrate that consisted of spun cast PEDOT:PSS film on an indium tin oxide (ITO) coated glass substrate. The PDMS was then removed, leaving the plastically deformed P3HT:PCBM film on the receiving substrate. In order for the strain alignment method to be successful, the P3HT:PCBM film should be highly deformable, which has previously been shown to depend on the local order of the P3HT in the blend film. The designated solution formulation and casting conditions, described above, resulted in a relatively low level of local order. This resulted in the ability to strain the films, by over 100%, without fracturing or tearing. After the strain and print process, the local order of the P3HT:PCBM was improved and OPV device performance was optimized by thermally annealing the films at 130° C. for 10 min, followed by slowly cooling the films to room temperature. To complete the OPV cell, the cathode, consisting of 1 nm of LiF and 100 nm Al, was deposited by vacuum thermal evaporation at a pressure of 1×10⁻⁶ mbar.

The in-plane orientation of the P3HT in the strain-aligned films was characterized using ultraviolet-visible (UV-vis) optical absorption spectroscopy under polarized illumination. The absorbance of the films, measured with linearly polarized light both parallel and perpendicular to the strain direction, is provided in FIG. 10A for films strained from 0% to 100% in 25% increments. These data demonstrate that, as the film is strained, there is an increase in the absorbance anisotropy that is indicative of in-plane P3HT alignment. Similar to strain-aligned neat P3HT films, the long axis of the polymer aligns in the direction of the applied strain. As observed in FIG. 10A, the polarized absorbance increases with strain and eventually plateaus after 50% strain. Meanwhile, the absorbance in the perpendicular direction continuously decreases with increasing strain. The plateau in the parallel direction occurs due to the competition between the increase in chain alignment and the decrease in film thickness resulting from the plastic deformation process. The dichroic ratio (R) of the P3HT:PCBM film (defined here as absorbance of light at a wavelength of 550 nm polarized parallel to the strain direction to light polarized perpendicular to the strain direction) with strain is given in FIG. 10B showing a non-linear relationship, and a dichroic ratio of 6.1 achieved for a 100% strained film. The dichroic ratio with strain at a wavelength of 605 nm is also provided in the TABLE below.

TABLE
Optical and electrical characteristics of strain aligned OPV cells with
various applied strains tested under polarized light parallel (||)
and perpendicular (⊥) to strain direction. Data includes the Dichroic
ratio (R), solar cell efficiency (η) and short circuit current (J_{SC}).

| | | R | R | η | J_{SC} |
|---|---|---|---|---|---|
| Film | (\|\|/⊥) | (550 nm) | (605 nm) | (%) | (mA cm⁻²) |
| 0% | \|\| | 0.97 | 0.97 | 3.01 | 3.93 |
| 0% | ⊥ | | | 3.05 | 3.98 |
| 25% | \|\| | 1.66 | 1.75 | 3.54 | 4.00 |
| 25% | ⊥ | | | 3.22 | 3.70 |
| 50% | \|\| | 2.70 | 3.20 | 3.63 | 4.09 |
| 50% | ⊥ | | | 2.78 | 3.26 |
| 75% | \|\| | 3.88 | 5.08 | 3.25 | 3.67 |
| 75% | ⊥ | | | 2.12 | 2.63 |
| 100% | \|\| | 6.10 | 9.68 | 2.90 | 3.53 |
| 100% | ⊥ | | | 1.81 | 2.23 |

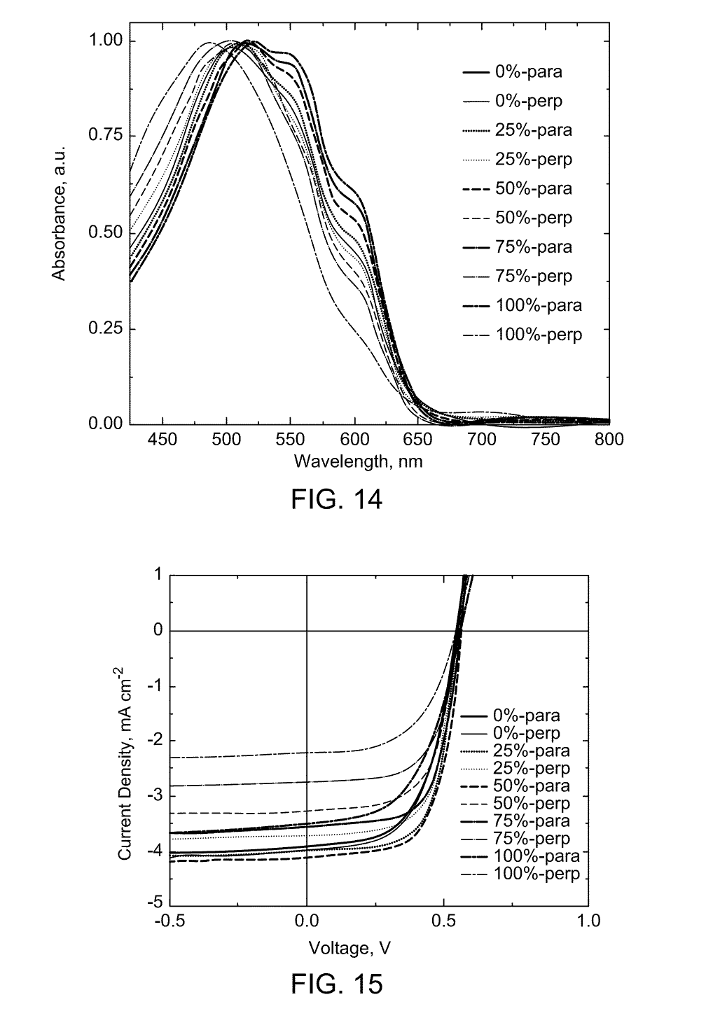

In addition to the average in-plane orientation of P3HT, the absorbance features provide information on the polymer aggregate character. This is observed through the appearance of the vibronic features in the absorbance spectrum and the relative magnitude of the of the 0-0 transition (near ≈550 nm) and the 0-1 transition (near ≈605 nm). It is observed that in the strained films, after thermal annealing, the absorbance ratio of the 0-0/0-1 transition is significantly smaller for polarized light parallel to the strain direction than polarized light perpendicular to the strain direction. This difference in absorbance is highlighted in the normalized absorbance provided in the supplemental information below (FIG. 14). This indicates that the P3HT with its backbone primarily aligned in the direction of strain consists of aggregates with greater local order, similar to the alignment observed in neat P3HT films.

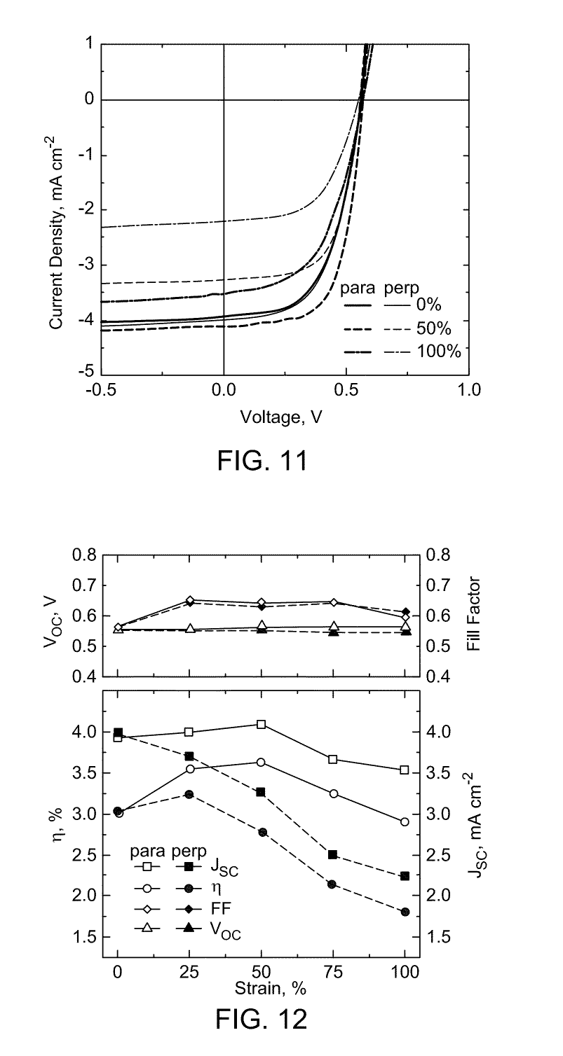

The aligned P3HT:PCBM films were processed into OPV cells, as described above, to determine how the anisotropic morphology translates to optoelectronic performance. The active area of the cell, defined by the cathode, was 3.14 mm² and the devices were tested using a Newport 150 W solar simulator with an AM1.5G filter under linear polarized light at an intensity of 41 mWcm⁻². The data is presented for 0%, 50%, and 100% strained P3HT:PCBM films with additional data for films strained by other amounts given in supplemental information. The current density (J)—voltage (V) characteristics for the strain-aligned BHJ OPV cells are provided in FIG. 11 (with additional data given in FIG. 15). It is observed that the 0% strained device shows nominally identical performance with polarized illumination in two orthogonal directions. As the applied strain is increased the polarization sensitivity of the film is increased and the difference in performance under polarized light in the parallel and perpendicular directions diverge. It is important to note that the efficiency of the 0% strained devices is comparable to solar cells processed in house without the transfer printing process. This suggests that the print process does not significantly degrade device performance, which is in agreement to previous reports that use similar processing methods. To further compare differences in performance, the open circuit voltage (V_{OC}), fill factor (FF), short circuit current (J_{SC}), and power conversion efficiency (η) of the strain-aligned devices is provided in FIG. 12. These results demonstrate that the open circuit voltage and FF are not significantly affected by the alignment of the polymer chains in the active layer. Rather, it is found that the variation in device performance is primarily driven by the change in short circuit current (J_{SC}). This is expected given that the diverging absorption will result in a similar variation in the exciton generation rate that in turn dictates J_{SC}. It is also found that the J_{SC} ratio is proportional to strain with similar behavior as the dichroic ratio, as shown in FIG. 10B, with the highest J_{SC} ratio of 1.6 achieved for the OPV cell with a 100% strained P3HT:PCBM film. The data is provided for performance under polarized light parallel (para) and perpendicular (perp) to the strain direction under 41 mWcm⁻² intensity.

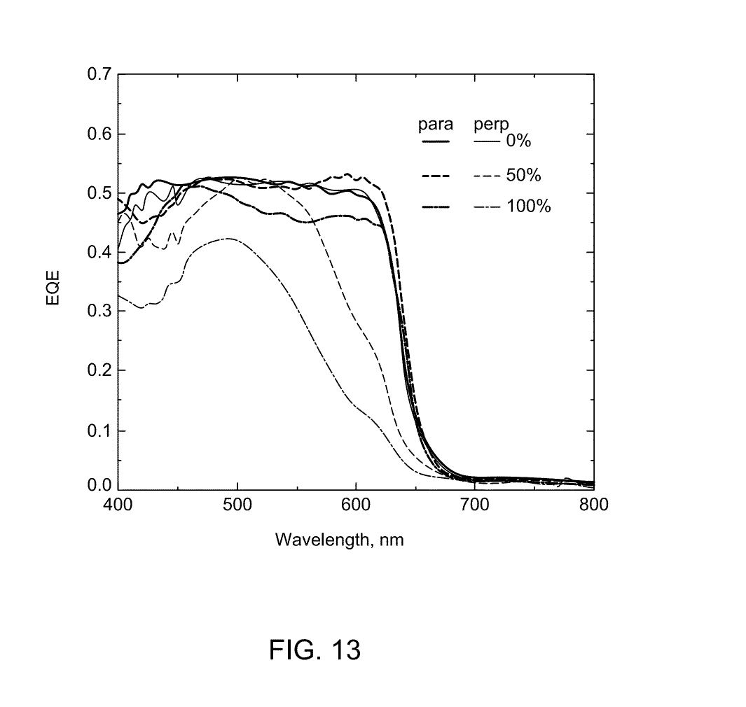

The external quantum efficiency (EQE) of the OPV cells, measured under polarized light, is provided in FIG. 13. The EQE for the strain-aligned OPV cells under polarized light is shown for three strains (0%, 50%, and 100%). The legend provides the level of strain applied to the P3HT:PCBM layer with light polarized parallel (para) and perpendicular (perp) to the strain direction. It is observed that the variation in EQE tracks well with the absorbance characteristics of the P3HT in the film, where parallel polarized light has greater conversion efficiency at extended wavelengths due to the absorption of the aligned P3HT aggregates. The J_{SC}, predicted from integrating the product of the EQE and AM1.5G photon flux, was within ±10% of the measured J_{SC} with the solar simulator. The discrepancy between the actual and predicted J_{SC} is most likely due to not accounting for spectral mismatch of the solar simulator, device-to-device variation, and device testing in atmosphere without encapsulation resulting in minor degradation during testing. Notable is that the EQE and J_{SC} for light linearly polarized parallel to the strain direction, does not change substantially for strains up to 50%. This is contrary to the absorbance, where the total absorbance for light polarized parallel to the strain direction, initially increases with increasing strain and then plateaus. The difference is due to the fact that the OPV cells have a reflective back electrode such that the light absorption is relatively complete for light polarized parallel to the strain direction for the levels of alignment and film thickness under consideration. At higher strains the absorption of polarized light parallel to the strain direction likely begins to decrease resulting in the drop in EQE and J_{SC}. The fact that the total light absorption is relatively complete for light polarized parallel to the direction of strain and the related power conversion efficiency (PCE) is maintained suggests that this processing approach aligns the polymer chains while maintaining film quality. For the device performance with light perpendicular to the strain direction, the total absorption in the OPV cell will decrease continuously with strain and is believed to be the primary cause of performance variation.

This Example demonstrates that polarized OPV cells have unique device capabilities that may be advantageous in many optical detection and energy harvesting applications, including those described herein. This Example presents a novel strain alignment method to fabricate polarization sensitive OPV cells. The ductility of the P3HT:PCBM cell is achieved by solution formulation and casting conditions that limit the P3HT local order in the as-cast films. The relatively high solar cell performance is achieved by thermally annealing the strained-aligned bulk heterojunction (BHJ) layer after printing onto the partially fabricated OPV device. The anisotropic performance in the aligned devices is primarily driven by the anisotropic absorption in the films. Additional details of the energy conversion variation in strain-aligned OPV cells will be conducted in a future study. Critically, this processing approach is able to create linearly polarized bulk-heterojunction organic photovoltaic devices with fine control over of the level of optical anisotropy while maintaining high performance P3HT:PCBM PV cells.

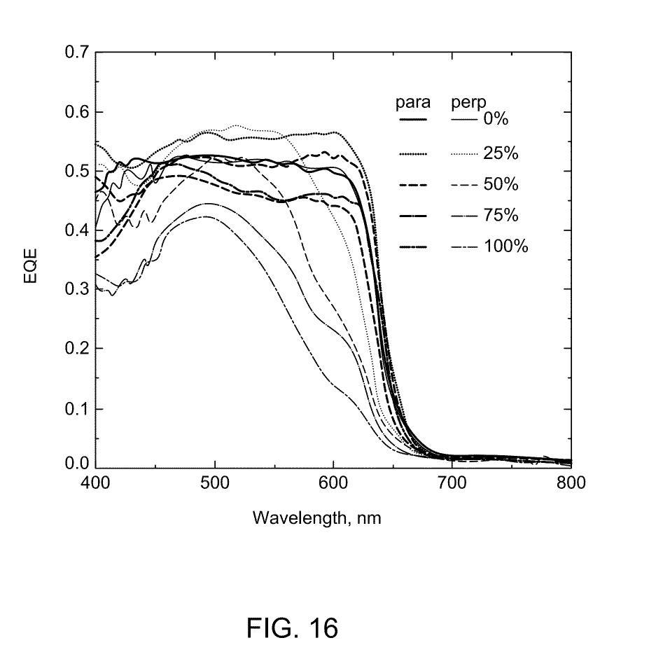

FIGS. 14 to 16 provide additional data relating to the Example above. FIG. 14 is a set of plots of normalized absorbance (arbitrary units) as a function of wavelength (nm) for the strain aligned P3HT:PCBM films with light polarized (para) and perpendicular (perp) to the strain direction. FIG. 14 highlights the variation in vibronic features in the strained films with light polarized parallel and perpendicular to the direction of strain. FIG. 15 is a set of current-voltage characteristics for the polarization sensitive photovoltaic cells for various levels of strain applied to the P3HT:PCBM layer. Current density is given in mA cm⁻². The measurements are given for linear polarized light parallel (para) and perpendicular (perp) to the strain direction at an intensity of 41 mW cm⁻². FIG. 16 is a set of plots of External Quantum Efficiency (EQE) as a function of wavelength (nm) for the strain-aligned OPV cells under polarized light shown for all strains being considered in this Example. The legend provides the level of strain applied to the P3HT:PCBM layer with light polarized parallel (para) and perpendicular (perp) to the strain direction.

An example of a method for calibrating a PV device as described herein will now be described. The method may include two processes. First, a radiometric calibration is performed such that all the pixels or detector elements across all focal plane arrays or sensors report identical outputs given identical inputs. Second, a polarimetric calibration, which focuses on characterizing the system's measurement matrix, W, is performed. Inversion of W yields a data reduction matrix that enables calculation of the input Stokes parameters at each spatial location within the scene. Note that this calibration procedure may also include an iterative step to account for other non-ideal effects within the polarimeter structure, such as may be caused by multiple reflections or angle-of-incidence effects.

To produce reliable polarimetric data, the digital number (DN) from the detector must be converted to a radiometric quantity. A linear detector's digital output can be expressed as,

DN(m, n)=R(m, n)Φ(m, n)+Off(m, n), (2)

where m, n are the integer pixel coordinates, R is the pixel responsivity, Φ is the photon flux, and Off is the offset. For radiometric calibration of the sensor, all pixels' responsivities and offsets must be calculated.

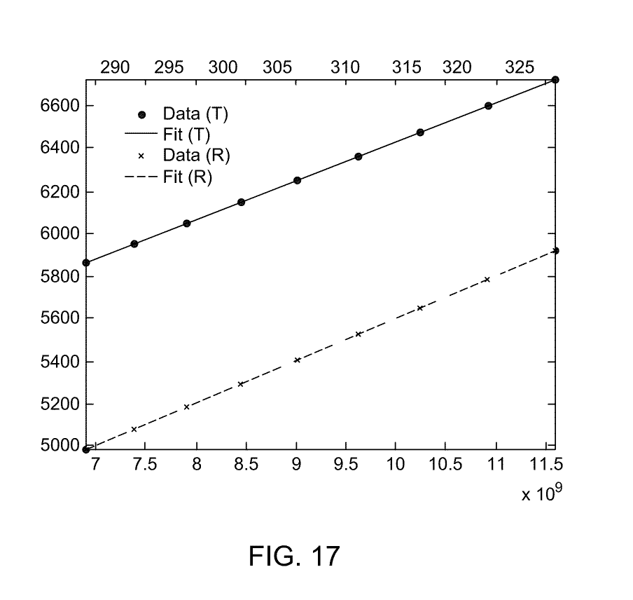

To achieve this, a black body or a NIST-traceable (National Institute of Standards and Technology) tungsten-halogen lamp is first diffused (e.g., using an integrating sphere or a large area emitter) and placed close to the front objective of the system so that it fills the entrance pupil. The radiant exitance (e.g., temperature of the black body or lamp intensity) of the source is then changed to various known values and a linear function is fitted for each pixel output versus the incident irradiance on the FPA (proportional to T_{bb}⁴ per Stefan-Boltzmann in the case of a perfect black body for all wavelengths). Extrapolation of the fitted function to an input temperature of 0 K yields Off while the slope of the line indicates the responsivity R. FIG. 17 illustrates the linearity of a microbolometer detector by depicting the raw data for the center pixel in DN alongside the fitted line as a function of T_{bb}⁴. More particularly, FIG. 17 shows FPA output and its corresponding fitted line for each microbolometer. The temperature T_{bb} of the black body was varied from 15° C. (288 K) to 55° C. increments. All pixels will yield the same output at each of the input temperatures by inverse mapping; e.g., converting DN to T_{bb}⁴, which is directly proportional to the incident irradiance. While this graph depicts the response for an infrared detector, similar trends are observed in visible photovoltaic and photoconductive detectors.

As mentioned previously, the goal of the polarimetric calibration is characterization of the system's measurement matrix W. This is consistent with the matrix approach for calibration,

P_{m,n}=W_{m,n}S_{m,n}, (3)

where Pm,n is a matrix of intensity measurements, Wm,n is the measurement matrix, and Sm,n is the incident Stokes vector. Using the pseudo-inverse of W, the Stokes vector can be calculated by,

S_{m,n}=W_{m,n}⁻¹P_{m,n}, (4)

where W⁻¹_{m,n} is the system's data reduction matrix. To characterize W, the instrument's analyzing elements (i.e., the WGBS, WP, etc.) are setup in a series of Mueller matrices with various free parameters (e.g., an element's orientation, retardance, etc.). Known polarization states are input into the instrument over the entire field of view (FOV) by use of a polarization generator. The theoretical output at each pixel is then fit, in a least squares fashion, to the measured output using the free parameters in the Mueller matrices. Primary consideration must be given to the condition number of the matrix W to ensure it has a low condition number. This ensures that the reconstructed Stokes parameters contain minimal sensitivity to noise contained within the measurement.

Propagation of the polarization state through an optical system via Stokes vectors is accomplished by representing each optical element by its Mueller matrix. In order to fully characterize the system's polarimetric response, and therefore calibrate its output, polarization attributes of the optical elements must be measured and their Mueller matrices calculated. A general Mueller matrix contains 4×4 elements,

$$M = [ \begin{matrix}{m}_{00} & {m}_{01} & {m}_{02} & {m}_{03} \\ {m}_{10} & {m}_{11} & {m}_{12} & {m}_{13} \\ {m}_{20} & {m}_{21} & {m}_{22} & {m}_{23} \\ {m}_{30} & {m}_{31} & {m}_{32} & {m}_{33}\end{matrix} ] . \qquad ( 5 )$$

There are two fundamental Mueller matrices that can be used to express an optical element's polarization interaction. The first is a diattenuator, which can be expressed in general as,

$${M}_{D} ( {T}_{x} , {T}_{y} , θ ) = \frac{1}{2} R ( - θ ) [ \begin{matrix}( {T}_{x} + {T}_{y} ) & ( {T}_{x} - {T}_{y} ) & 0 & 0 \\ ( {T}_{x} - {T}_{y} ) & ( {T}_{x} + {T}_{y} ) & 0 & 0 \\ 0 & 0 & 2 \sqrt{{T}_{x} {T}_{y}} & 0 \\ 0 & 0 & 0 & 2 \sqrt{{T}_{x} {T}_{y}}\end{matrix} ] R ( θ ) , \qquad ( 6 )$$

where Tx, Ty are the transmission ratios in the x and y directions, θ is the angle at which the diattenuator is oriented (as measured from the x-axis), and R(θ) is the Mueller rotation matrix,

$$R ( θ ) = [ \begin{matrix}1 & 0 & 0 & 0 \\ 0 & cos ( 2 θ ) & sin ( 2 θ ) & 0 \\ 0 & - sin ( 2 θ ) & cos ( 2 θ ) & 0 \\ 0 & 0 & 0 & 1\end{matrix} ] . \qquad ( 7 )$$

The diattenuation matrix can be re-expressed as a function of the diattenuation coefficient (D), after normalization to (Tx+Ty),

$${M}_{D} ( D , E , θ ) = \frac{1}{2} R ( - θ ) [ \begin{matrix}1 & D & 0 & 0 \\ D & 1 & 0 & 0 \\ 0 & 0 & 2 E & 0 \\ 0 & 0 & 0 & 2 E\end{matrix} ] R ( θ ) , \qquad ( 8 )$$

where D and E are defined as,

$$D = \frac{( {T}_{x} - {T}_{y} )}{( {T}_{x} + {T}_{y} )} , E = \frac{\sqrt{{T}_{x} {T}_{y}}}{( {T}_{x} + {T}_{y} )} \qquad ( 9 )$$

and (Tx+Ty) is removed as a multiplying factor of Eq. 8, implying normalization of the analyzer vector to the m₀₀ component, or similarly to the S₀ component of the output Stokes vector. Secondly is a retarder, which can be generally expressed by,

$${M}_{R} ( δ , θ ) = R ( - θ ) [ \begin{matrix}1 & 0 & 0 & 0 \\ 0 & 1 & 0 & 0 \\ 0 & 0 & cos δ & - sin δ \\ 0 & 0 & sin δ & cos δ\end{matrix} ] R ( θ ) , \qquad ( 10 )$$

where δ is the retardance induced by the element, and is a measure of the relative phase delay between the eigenvectors of M_{R}. An analyzer vector (A) is given by the first row of the Mueller matrix,

A=[m₀₀ m₀₁ m₀₂ m₀₃]. (11)

The measurement matrix is composed of the analyzer vectors for each analyzer configuration,

$$W = [ \begin{matrix}{A}_{1} \\ {A}_{2} \\ ⋮ \\ {A}_{N}\end{matrix} ] = [ \begin{matrix}{m}_{00 , 1} & {m}_{01 , 1} & {m}_{02 , 1} & {m}_{03 , 1} \\ {m}_{00 , 1} & {m}_{01 , 2} & {m}_{02 , 2} & {m}_{03 , 2} \\ ⋮ & ⋮ & ⋮ & ⋮ \\ {m}_{00 , N} & {m}_{01 , N} & {m}_{02 , N} & {m}_{03 , N}\end{matrix} ] . \qquad ( 12 )$$

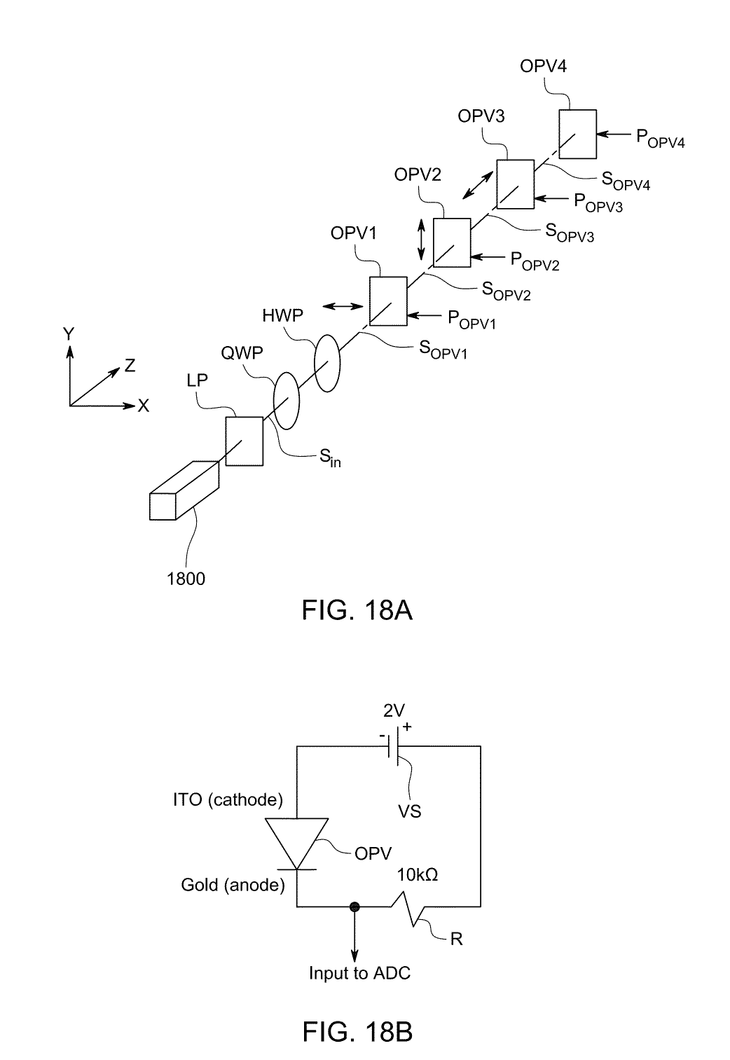

To calibrate the system, its measurement matrix was determined. Light, with a known polarization state was used to illuminate the system, and the responses of the 4 OPVs were measured. A view of the polarimeter's experimental configuration is shown in FIG. 18A, which illustrates a diagram of an example experimental setup for calibrating the polarimeter in accordance with embodiments of the present disclosure. Referring to FIG. 18A, light travels from a laser 1800 along the Z-axis. The setup includes a linear polarizer LP, a quarter waveplate QWP, and a half waveplate HWP. OPV cells OPV1, OPV2, and OPV3 are arrange at 0°, 90°, and 45°. OPV cell OPV4 is not strain aligned and can be placed at any orientation. The light source was a 532 nm laser diode with polarization at 0° to the x-axis. A calcite Glan-Taylor linear polarizer (LP), which also has its transmission axis parallel to x-axis, is introduced after the laser 1800 to clean up the laser's polarization state such that the input polarization into the system is

Sᵢₙ=[1 1 0 0]¹. (1)

A quarter waveplate (QWP), followed by a half waveplate (HWP), further modify the polarization state of the incident light and also helped to introduce known circular polarization states. S_{OPVi} denotes the Stokes vector incident on OPVi, where i is an integer spanning 1-4 to denote one of the four OPV cells. Similarly, P_{OPVi} denotes the voltage measurement taken from the i^{th} OPV cell. As depicted in FIG. 18B, the OPVs are reverse biased by a 2 V source VS and the voltage across the load resistance (10 kΩ) R is measured by a micro-controller or Oscilloscope and recorded on a computer. Referring to FIG. 18B, the load resistor R is 10 kΩ, and the input voltage is 2 V, supplied by a suitable power supply.

The Mueller matrices of the QWP (M_{QWP}) and HWP (M_{HWP}), with fast axis horizontal, are expressed as,

$$\begin{matrix}{M}_{QWP} = [ \begin{matrix}1 & 0 & 0 & 0 \\ 0 & 1 & 0 & 0 \\ 0 & 0 & 0 & - 1 \\ 0 & 0 & 1 & 0\end{matrix} ] , & ( 2 ) \\ {M}_{HWP} = [ \begin{matrix}1 & 0 & 0 & 0 \\ 0 & 1 & 0 & 0 \\ 0 & 0 & 1 & 0 \\ 0 & 0 & 0 & - 1\end{matrix} ] . & ( 3 )\end{matrix}$$

The QWP and HWP were rotated by 360°, in steps of 45°, generating 81 sets of response measurements from each of the 4 OPVs. This modified S_{OPV1} for each orientation of the waveplates according to

S_{OPV1}=R(θ₁)M×_{HWP} R(−θ₁)×R(θ₂)M×_{QWP} R(−θ₂) ×S_{IN}×, (4)

where, 0₁ and 0₂ are the fast axis orientation angles of the HWP and QWP respectively, measured with respect to the horizontal x-axis.

The intensity measurements from all four OPVs (P) depends on the Stokes vector incident onto the first cell (S_{OPV1}) and the measurement matrix, W. These can be expressed as,

P=W S×_{OPV}, (5)

where W is a 4×4 matrix, such that,

$$W = [ \begin{matrix}{w}_{11} & {w}_{12} & {w}_{13} & {w}_{14} \\ {w}_{21} & {w}_{22} & {w}_{23} & {w}_{24} \\ {w}_{31} & {w}_{32} & {w}_{33} & {w}_{34} \\ {w}_{41} & {w}_{42} & {w}_{43} & {w}_{44}\end{matrix} ] . \qquad ( 6 )$$

A MATLAB model of the system was used to simulate the system with the OPVs and the waveplates. To model the transmission and absorption of each OPV, the following equation was used:

p+r+t=1, (7)

where p is absorbance, r is reflectance and t is transmittance. It was assumed that r=0, in other words, the light that was not transmitted was being absorbed. From the Mueller matrices of the OPVs, Tₓ and T_{y} were determined as per Eq. (3) and the transmission Mueller matrices were constructed. The absorption Mueller matrices were computed using 1−Tₓ and 1−T_{y} as the variables, as per Eq. (15) and the assumption r=0.

The analyzer vectors for the OPVs may be defined as:

Mᵢ=ARᵢ×ATᵢ₋₁×ATᵢ₋₂ . . . ×AT (8)

where Mᵢ is the i^{th} analyzer vector, ARᵢ is the absorption matrix for i^{th} OPV and ATᵢ₋₁ i is the transmission matrix for i−1^{th} OPV. The first row of the i^{th} analyzer vector was the i^{th} row of the measurement matrix. So, from 4 analyzer vectors we had the full 4×4 measurement matrix.

Using Eq. (16) and the characterization data presented previously in Table 1, we can compute the theoretical measurement matrix W for the OPV polarimeter as

$$W = [ \begin{matrix}{m}_{11 , opv 1} & {m}_{12 , opv 1} & {m}_{13 , opv 1} & {m}_{14 , opv 1} \\ {m}_{11 , opv 2} & {m}_{11 , opv 2} & {m}_{11 , opv 2} & {m}_{11 , opv 2} \\ {m}_{11 , opv 3} & {m}_{11 , opv 3} & {m}_{11 , opv 3} & {m}_{11 , opv 3} \\ {m}_{11 , opv 4} & {m}_{11 , opv 4} & {m}_{11 , opv 4} & {m}_{11 , opv 4}\end{matrix} ] , \qquad ( 9 )$$

where each row is the analyzer vector for each OPVs Mueller matrix.

To empirically measure W, the Stokes vectors of light, incident on different OPVs and their responses can be used. The 4 OPVs can each solve for a row of W, using the following equation:

$$[ \begin{matrix}{P}_{i , 0} \\ {P}_{i , 1} \\ ⋮ \\ {P}_{i , Q}\end{matrix} ] [ \begin{matrix}{S}_{0 , 0} & {S}_{1 , 0} & {S}_{2 , 0} & {S}_{3 , 0} \\ {S}_{0 , 1} & {S}_{1 , 1} & {S}_{2 , 1} & {S}_{3 , 1} \\ ⋮ & ⋱ & & ⋮ \\ {S}_{0 , Q} & {S}_{0 , Q} & {S}_{0 , Q} & {S}_{0 , Q}\end{matrix} ] \times [ \begin{matrix}{w}_{j 1} \\ {w}_{j 2} \\ {w}_{j 3} \\ {w}_{j 4}\end{matrix} ] , \qquad ( 10 )$$

where Q is the total number of measurements, the subscript i denotes the ith OPV, while S₀, S₁, S₂, and S₃ are Stokes parameters of light, incident on ith OPV, and subscript j is row number of W matrix.

The Stokes vectors of incident light are dependent on the Mueller matrices of the OPVs. In section III, the Mueller matrices of the OPV were computed, which were used to determine the Stokes vectors of the incident light. Extracting separate equations from Eq. (18) yields,

P_{i,q}=w_{i,1}S_{0,q}+w_{j,2}S_{1,q}+w_{j,3}S_{2,q}+w_{j,4}S_{3,q}, (11)

where q denotes qth measurement. Thus, for each row of W, we obtained Q equations, which were solved to determine the elements of W.

For purposes of the present disclosure, it will be understood that when a layer (or film, region, substrate, component, device, or the like) is referred to as being “on” or “over” another layer, that layer may be directly or actually on (or over) the other layer or, alternatively, intervening layers (e.g., buffer layers, transition layers, interlayers, sacrificial layers, etch-stop layers, masks, electrodes, interconnects, contacts, or the like) may also be present. A layer that is “directly on” another layer means that no intervening layer is present, unless otherwise indicated. It will also be understood that when a layer is referred to as being “on” (or “over”) another layer, that layer may cover the entire surface of the other layer or only a portion of the other layer. It will be further understood that terms such as “formed on” or “disposed on” are not intended to introduce any limitations relating to particular methods of material transport, deposition, fabrication, surface treatment, or physical, chemical, or ionic bonding or interaction. The term “interposed” is interpreted in a similar manner.

In general, terms such as “communicate” and “in . . . communication with” and “coupled” (for example, a first component “communicates with” or “is in communication with” a second component, or a first component “is coupled to” a second component) are used herein to indicate a structural, functional, mechanical, electrical, signal, optical, magnetic, electromagnetic, ionic or fluidic relationship between two or more components or elements. As such, the fact that one component is said to communicate with or be coupled to a second component is not intended to exclude the possibility that additional components may be present between, and/or operatively associated or engaged with, the first and second components.

It will be understood that various aspects or details of the invention may be changed without departing from the scope of the invention. Furthermore, the foregoing description is for the purpose of illustration only, and not for the purpose of limitation—the invention being defined by the claims.

What is claimed is:

1. A polarization sensitive photovoltaic (PV) cell, comprising:
an anode;
a cathode;
a photoactive layer between the anode and the cathode; and
a polarizing structure between the anode and the cathode,
wherein at least one of the anode and the cathode is transparent.

2. The PV cell of claim 1, wherein the anode is transparent, and the cathode is reflective, opaque or transparent.

3. The PV cell of claim 1, wherein the polarizing structure is embedded in or a feature of the photoactive layer.

4. The PV cell of claim 1, wherein the photoactive layer comprises an inorganic p-type material and an inorganic n-type material forming a p-n junction.

5. The PV cell of claim 4, wherein the polarizing structure comprises an array of parallel bars formed at the p-n junction.

6. The PV cell of claim 1, wherein the photoactive layer comprises an electron donor material and an electron acceptor material forming a heterojunction, and at least one of the electron donor material and the electron acceptor material is an organic polymer.

7. The PV cell of claim 6, wherein the polarizing structure comprises an array of polymer backbones aligned in parallel with each other, and the polymer backbones are part of the organic polymer.

8. The PV cell of claim 1, wherein the polarizing structure comprises a plurality of portions between the anode and cathode having different polarization sensitivities.

9. The PV cell of claim 8, wherein the portions include respective arrays of parallel structures oriented in different directions relative to each other.

10. A polarization sensitive photovoltaic (PV) device, comprising:
a first PV cell comprising a first anode, a first cathode that is transparent, a first photoactive layer between the first anode and the first cathode; and
a second PV cell comprising a second transparent anode, a second cathode, and a second photoactive layer between the second anode and the second cathode,
wherein the first PV cell and the second PV cell are stacked along a device axis such that the first cathode is in electrical communication with the second anode.

11. The PV device of claim 10, wherein the polarizing structure of the first PV cell is a first polarizing structure, the first polarizing structure is oriented at a first angle in a transverse plane orthogonal to the device axis, the second PV cell comprises a second polarizing structure between the second anode and the second cathode, and the second polarizing structure is oriented at a second angle different from the first angle.

12. The PV device of claim 10, comprising one or more additional PV cells stacked along the device axis, wherein at least one of the additional PV cells comprises an additional polarizing structure oriented at an angle different from the first angle and the second angle.

13. The PV device of claim 11, comprising a third PV cell and a fourth PV cell, wherein the third PV cell comprises a third polarizing structure oriented at a third angle different from the first angle and the second angle.

14. The PV device of claim 13, wherein the fourth PV cell does not include a polarizing structure.

15. A method for fabricating a polarization sensitive photovoltaic (PV) cell, the method comprising:
forming an anode, a cathode, and a photoactive layer such that the photoactive layer is between the anode and the cathode, wherein at least one of the anode and the cathode is transparent; and
forming a polarizing structure between the anode and the cathode.

16. The method of claim 15, wherein forming the polarizing structure comprises embedding the polarizing structure in the photoactive layer or processing the photoactive layer to include the polarizing structure.

17. The method of claim 15, wherein forming the photoactive layer comprises forming a p-n junction.

18. The method of claim 17, wherein forming the polarizing structure comprises forming an array of parallel bars at the p-n junction.

19. The method of claim 18, wherein forming the array comprises subjecting the p-n junction to a microfabrication process.

20. The method of claim 15, wherein forming the photoactive layer comprises forming a heterojunction of an electron donor material and an electron acceptor material, and at least one of the electron donor material and the electron acceptor material is an organic polymer.

21. The method of claim 20, wherein forming the polarizing structure comprises forming an array of polymer backbones of the organic polymer such that the polymer backbones are aligned in parallel with each other.

22. The method of claim 21, wherein forming the array comprises subjecting the organic polymer to a uniaxial straining process.

23. A method for fabricating a polarization sensitive photovoltaic (PV) device, the method comprising:
fabricating a first PV cell comprising an anode, a cathode, a photoactive layer between the anode and the cathode, a polarizing structure between the anode and the cathode, and wherein at least one of the anode and the cathode is transparent;
fabricating one or more additional PV cells, with or without respective polarizing structures; and
stacking the first PV cell and the one or more additional PV cells along an axis.

24. The method of claim 23, wherein:
the polarizing structure of the first PV cell is a first polarizing structure, and the first polarizing structure is oriented at a first angle in a transverse plane orthogonal to the device axis; and
fabricating the one or more additional PV cells comprises fabricating a second PV cell, the second PV cell comprising a second polarizing structure oriented at a second angle different from the first angle.
